(19) United States
(12) Patent Application Publication
(10) Pub. No.: US 2026/0018648 A1
(43) Pub. Date: Jan. 15, 2026

(54) AUTOMATIC GROUPING METHOD FOR TRACTION BATTERY USED IN ELECTRIC VEHICLE

(71) Applicant: LEOCH INTERNATIONAL HOLDING PTE. LTD., SINGAPORE (SG)

(72) Inventors: Daoxiang NIU, SINGAPORE (SG); Yongtao MA, SINGAPORE (SG); Ning WANG, SINGAPORE (SG); Feng XIAO, SINGAPORE (SG); Long NIU, SINGAPORE (SG); Jintao CHEN, SINGAPORE (SG)

(21) Appl. No.: 19/333,404

(22) Filed: Sep. 19, 2025

Related U.S. Application Data
(63) Continuation of application No. PCT/CN2024/117827, filed on Sep. 9, 2024.

(30) Foreign Application Priority Data
Apr. 15, 2024 (CN) 202410449597.1

(51) Int. Cl. H01M 10/04; B60L 50/64; G01R 31/36; G01R 31/385; G01R 31/396; H01M 10/42

(52) U.S. Cl. CPC H01M 10/0404; B60L 50/64; G01R 31/3646; G01R 31/3865; G01R 31/396; H01M 10/4285

(57) ABSTRACT

Provided is an automatic grouping method for a traction battery used in an electric vehicle. The method includes: step 1: collecting battery data; step 2: storing and aggregating data; step 3: grouping the battery information: grouping, by the computer, the plurality of batteries based on a grouping condition, labeling, by the computer, the plurality of batteries with a cut-off voltage, a discharge period, grouping information, and a date, and directly rejecting a battery that meets a screening condition; step 4: printing and pasting a barcode; and step 5: screening and grouping the plurality of batteries.

### CROSS-REFERENCE TO RELATED APPLICATION

This application is a continuation of International Patent Application No. PCT/CN2024/117827, filed on Sep. 9, 2024, which claims priority to Chinese patent application No. 202410449597.1, titled “AUTOMATIC GROUPING METHOD FOR TRACTION BATTERY USED IN ELECTRIC VEHICLE,” and filed on Apr. 15, 2024, both of which are incorporated herein by reference in their entireties.

### FIELD

The present disclosure relates to the field of battery technologies, and more particularly, to an automatic grouping method for a traction battery used in an electric vehicle.

### BACKGROUND

With the continuous development of a new energy industry, a battery, as a safe, energy-saving, and environmentally friendly product, is widely used in an electric vehicle, an electric bicycle, an electric utility vehicle, a hybrid vehicle, a sightseeing vehicle, an electric patrol vehicle, an electric flatbed truck, a municipal engineering vehicle, a property management vehicle, and an electric bus, and other fields. To make a traction battery have a high voltage and a high current, the batteries are usually connected in series in a certain sequence to form a series battery, and then a plurality of series batteries are connected in parallel to form the required traction battery.

Consistency among individual batteries in the traction battery is a key to prolonging a service life of a battery pack. When a discharge period and a cut-off voltage of one battery in the traction battery are lower than those of other batteries, a service life of the entire battery pack may be greatly shortened. Therefore, before assembling the traction battery, the battery needs to be tested. Due to complex requirements for traction battery grouping, manual grouping involves high difficulty and a heavy workload, resulting in a low grouping efficiency and affecting a manufacturing efficiency of the traction battery.

### SUMMARY

The present disclosure aims at a problem of a low grouping efficiency caused by high difficulty and a heavy workload of manual grouping of a traction battery in the related art, and provides the following technical solution.

An automatic grouping method for a traction battery used in an electric vehicle is provided. The method includes: step 1: collecting battery data: conveying, by a main belt conveyor, a plurality of batteries to pass through a detection device in sequence, and making contact with, by the detection device, positive electrodes and negative electrodes of the plurality of batteries to obtain battery information; step 2: storing and aggregating data: transmitting, by the detection device, data of the battery information to a computer connected to the detection device, and storing, by the computer, the battery information in a predefined data table; step 3: grouping the battery information: grouping, by the computer, the plurality of batteries based on a grouping condition, labeling, by the computer, the plurality of batteries with a cut-off voltage, a discharge period, grouping information, and a date, and directly rejecting a battery that meets a screening condition; step 4: printing and pasting a barcode: printing, by the computer, labeled information on a label by means of a barcode printing device connected to the computer, and pasting, by a labeling device connected to the computer, the label on a corresponding battery; and step 5: screening and grouping the plurality of batteries: placing, by a manipulator connected to the computer based on the labeled information, the plurality of batteries on a secondary belt conveyor of a corresponding group, and processing and assembling the plurality of batteries in a same group into a complete traction battery.

As a preferred embodiment of the above technical solution, the grouping condition in the step 3 is: setting a starting value of cut-off voltage data, and dividing the plurality of batteries into N large groups in sequence based on a predetermined cut-off voltage data interval; setting a starting value of discharge period data in a same large group, and dividing the plurality of batteries into N small groups in sequence based on a predetermined discharge period data interval; and dividing, by the computer, the plurality of batteries into a corresponding small group in a corresponding large group based on a cut-off voltage and a discharge period, where N is a natural number greater than 1.

As a preferred embodiment of the above technical solution, the grouping condition in the step 3 is: setting a starting value of cut-off voltage data, and dividing the plurality of batteries into N large groups in sequence based on a predetermined cut-off voltage data interval; setting a starting value of discharge period data in a same large group, and dividing the plurality of batteries into M small groups in sequence based on a predetermined discharge period data interval; and dividing, by the computer, the plurality of batteries into a corresponding small group in a corresponding large group based on a cut-off voltage and a discharge period, where each of N and M is a natural number greater than 1, and N is different from M.

As a preferred embodiment of the above technical solution, the screening condition in the step 3 is: the cut-off voltage data of the battery is lower than the starting value of the cut-off voltage data, or the discharge period of the battery is lower than the starting value of the discharge period data.

As a preferred embodiment of the above technical solution, the labeling device includes a drive assembly, a connection assembly, and a suction head. The connection assembly is configured to connect the drive assembly and the suction head. The connection assembly includes a mounting housing and a telescopic rod. An end of the telescopic rod is movably inserted into the mounting housing in a vertical direction, a return spring being fixedly connected between the telescopic rod and the mounting housing. The drive assembly is configured to drive the suction head by means of the connection assembly to pick up the label from a label sheet. The suction head is configured to push the telescopic rod upwardly to paste the label to a surface of the battery.

As a preferred embodiment of the above technical solution, the telescopic rod has a first end located inside the mounting housing, and a second end located outside the mounting housing, the first end being connected to the return spring, and the second end being connected to the suction head.

As a preferred embodiment of the above technical solution, the connection assembly further includes a smoothing component, the smoothing component including a connection portion and a smoothing roller, and the connection portion being configured to move two smoothing rollers towards or away from each other by using a reciprocating movement of the telescopic rod in the vertical direction.

As a preferred embodiment of the above technical solution, the two smoothing rollers are located at two sides of the telescopic rod, respectively.

As a preferred embodiment of the above technical solution, the connection portion includes a driving gear. The telescopic rod has a toothed surface formed at a surface of the telescopic rod, the driving gear being engaged into the toothed surface. First bevel gears are coaxially arranged at two ends of the driving gear. Each of the first bevel gears is engaged with a second bevel gear at a side of the first bevel gear. The second bevel gear is coaxially provided with a driven gear at an end of the second bevel gear. The driven gear is engaged with a straight rack at a side of the driven gear. The straight rack is fixedly connected to a mounting frame at an end of the straight rack.

As a preferred embodiment of the above technical solution, the connection portion is symmetrically arranged relative to a middle part of the telescopic rod. The telescopic rod is not engaged with the driving gear at a bottommost position of the telescopic rod.

As a preferred embodiment of the above technical solution, an end of the smoothing roller is rotatably inserted into the mounting frame. The smoothing roller is in rolling engagement with the surface of the battery.

As a preferred embodiment of the above technical solution, after the telescopic rod moves upwardly by a predetermined distance, the toothed surface of the telescopic rod is engaged with the driving gear, the telescopic rod pushes the driving gear to rotate, the driving gear drives two first bevel gears to rotate, the two first bevel gears drive the second bevel gears corresponding to the two first bevel gears to rotate respectively, the second bevel gears drive the driven gear to rotate and enable the straight rack to move, and two straight racks drive the two smoothing rollers to move away from each other by means of the mounting frames.

Advantageous effects of the present disclosure are provided as follows.
1. The plurality of batteries pass through the detection device in sequence to obtain the battery information. The computer groups the plurality of batteries based on the grouping condition. The plurality of batteries are divided into a plurality of large groups based on the cut-off voltage data. In addition, the plurality of batteries in the same large group are divided into a plurality of small groups based on the discharge period. The plurality of batteries are automatically grouped and labeled by a machine device, which can reduce difficulty of battery grouping, improve an efficiency of battery grouping, and thus enhance a battery manufacturing efficiency.
2. Based on the grouping condition, the batteries can be divided into specific large groups based on the cut-off voltage data, and the batteries can be divided into specific small groups based on the discharge period data, making the grouping simpler and more convenient.
3. The disposed connection assembly can allow the suction head to retract slightly during a labeling process, avoiding excessive contact between the suction head and the surface of the battery to squeeze and deform the surface of the battery. In addition, a contact time between the label and the surface of the battery can be increased after the suction head is retracted, to enable the label to be more firmly pasted to the surface of the battery.
4. The disposed connection portion can use upward movement of the telescopic rod to move the two smoothing rollers away from each other. A smoothing roller in contact with a surface of the label rolls along an arc-shaped surface of the battery, to smooth a position at two ends of the label that is raised due to the arc-shaped surface of the battery being not in contact with the surface of the battery, to prevent the label from folding or detaching due to other factors, ensuring normal grouping operation.

### BRIEF DESCRIPTION OF THE DRAWINGS

FIG. 1 is a flowchart of operations according to an embodiment.

FIG. 2 is a schematic view of an overall structure of a connection assembly according to an embodiment.

FIG. 3 is a front cross-sectional view of a connection assembly according to an embodiment.

FIG. 4 is an operating state diagram of a connection portion according to the embodiment.

In the figures: 10 suction head; 20 connection assembly; 21 mounting housing; 22 telescopic rod; 23 return spring; 24 smoothing roller; 251 driving gear; 252 first bevel gear; 253 second bevel gear; 254 driven gear; 255 straight rack; 26 mounting frame.

### DETAILED DESCRIPTION

To make objectives, technical solutions, and advantages of embodiments of the present disclosure more apparent, the technical solutions according to the present disclosure will be described clearly and completely below in combination with embodiments and accompanying drawings.

### Embodiments

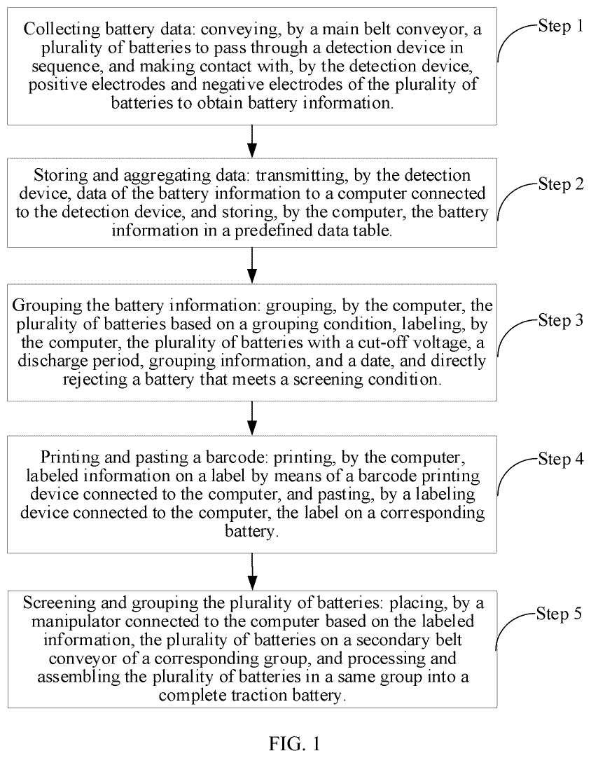

In FIG. 1, an automatic grouping method for a traction battery used in an electric vehicle is provided. The method includes: step 1: collecting battery data: conveying, by a main belt conveyor, a plurality of batteries to pass through a detection device in sequence, and making contact with, by the detection device, positive electrodes and negative electrodes of the plurality of batteries to obtain battery information; step 2: storing and aggregating data: transmitting, by the detection device, data of the battery information to a computer connected to the detection device, and storing, by the computer, the battery information in a predefined data table; step 3: grouping the battery information: grouping, by the computer, the plurality of batteries based on a grouping condition, labeling, by the computer, the plurality of batteries with a cut-off voltage, a discharge period, grouping information, and a date, and directly rejecting a battery that meets a screening condition; step 4: printing and pasting a barcode: printing, by the computer, labeled information on a label by means of a barcode printing device connected to the computer, and pasting, by a labeling device connected to the computer, the label on a corresponding battery; and step 5: screening and grouping the plurality of batteries: placing, by a manipulator connected to the computer based on the labeled information, the plurality of batteries on a secondary belt conveyor of a corresponding group, and processing and assembling the plurality of batteries in a same group into a complete traction battery.

The plurality of batteries pass through the detection device in sequence to obtain the battery information. The computer groups the plurality of batteries based on the grouping condition. The plurality of batteries are divided into a plurality of large groups based on the cut-off voltage data. In addition, the plurality of batteries in the same large group are divided into a plurality of small groups based on the discharge period. The plurality of batteries are automatically grouped and labeled by a machine device, which can reduce difficulty of battery grouping, improve an efficiency of battery grouping, and thus enhance a battery manufacturing efficiency.

In FIG. 1, the grouping condition in the step 3 is: setting a starting value of cut-off voltage data, and dividing the plurality of batteries into N large groups in sequence based on a predetermined cut-off voltage data interval; setting a starting value of discharge period data in a same large group, and dividing the plurality of batteries in the same large group into N small groups in sequence based on a predetermined discharge period data interval; and dividing, by the computer, the plurality of batteries into a corresponding small group in a corresponding large group based on a cut-off voltage and a discharge period. N is a natural number greater than 1.

Alternatively, the grouping condition in the step 3 is: setting a starting value of cut-off voltage data, and dividing the plurality of batteries into N large groups in sequence based on a predetermined cut-off voltage data interval; setting a starting value of discharge period data in a same large group, and dividing the plurality of batteries in the same large group into M small groups in sequence based on a predetermined discharge period data interval; and dividing, by the computer, the plurality of batteries into a corresponding small group in a corresponding large group based on a cut-off voltage and a discharge period. Each of N and M is a natural number greater than 1, and N is different from M.

Based on the grouping condition, the batteries may be divided into specific large groups based on the cut-off voltage data, and the batteries in the same large group may be divided into specific small groups based on the discharge period data, making the grouping simpler and more convenient.

In FIG. 1, the screening condition in the step 3 is: the cut-off voltage data of the battery is lower than the starting value of the cut-off voltage data, or the discharge period of the battery is lower than the starting value of the discharge period data.

The set screening condition can screen out and reject the battery that does not meet the grouping condition. After aggregating information of the battery that does not meet the grouping condition, manufacturing of the battery is adjusted based on information aggregating data, reducing a proportion of batteries that fail to meet the grouping condition.

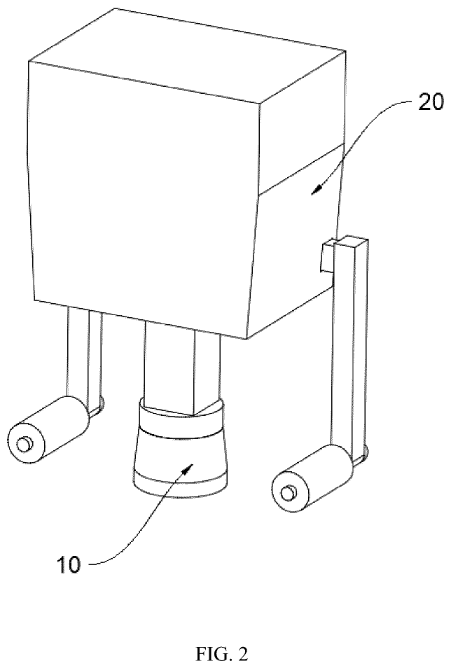

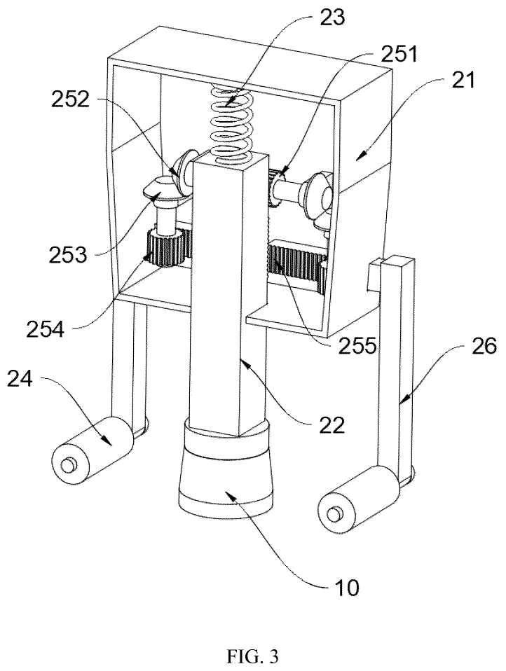

In FIG. 2 to FIG. 3, the labeling device includes a drive assembly, a connection assembly 20, and a suction head 10. The connection assembly 20 is configured to connect the drive assembly and the suction head 10. The connection assembly 20 includes a mounting housing 21 and a telescopic rod 22. An end of the telescopic rod 22 is movably inserted into the mounting housing 21 in a vertical direction, and a return spring 23 is fixedly connected between the telescopic rod 22 and the mounting housing 21. The drive assembly is configured to drive the suction head 10 by means of the connection assembly 20 to pick up the label from a label sheet. The suction head 10 is configured to push the telescopic rod 22 upwardly to paste the label to a surface of the battery.

The telescopic rod 22 has a first end located inside the mounting housing 21, and a second end located outside the mounting housing 21. The first end is connected to the return spring 23. The second end is connected to the suction head 10. As illustrated in FIG. 3, the first end of the telescopic rod 22 is, for example, an upper end, and the second end of the telescopic rod 22 is, for example, a lower end.

When the drive assembly drives the suction head 10 to move by means of the connection assembly 20, the suction head 10 moves to a position above the label sheet and removes the label, then the suction head 10 moves to a position above the battery to which the label needs to be pasted for labeling. When the suction head 10 moves downwardly to pick up the label or paste the label, the label sheet or the battery pushes the suction head 10 in a reverse direction to move the telescopic rod 22 upwardly, and the return spring 23 contracts accordingly to avoid excessive contact between the suction head 10 and the label sheet or the battery.

The disposed connection assembly 20 can allow the suction head 10 to retract slightly during a labeling process, avoiding excessive contact between the suction head 10 and the surface of the battery to squeeze and deform the surface of the battery. In addition, a contact time between the label and the surface of the battery can be increased after the suction head 10 is retracted, to enable the label to be more firmly pasted to the surface of the battery.

In FIG. 2 to FIG. 4, the connection assembly 20 further includes a smoothing component. The smoothing component includes a connection portion and a smoothing roller 24. The connection portion is configured to move two smoothing rollers 24 towards or away from each other by using a reciprocating movement of the telescopic rod 22 in the vertical direction. The two smoothing rollers 24 are located at two sides of the telescopic rod 22, respectively.

The connection portion includes a driving gear 251. The telescopic rod 22 has a toothed surface formed at a surface of the telescopic rod 22. The driving gear 251 is engaged into the toothed surface. First bevel gears 252 are coaxially arranged at two ends of the driving gear 251. Each of the first bevel gears 252 is engaged with a second bevel gear 253 at a side of the first bevel gear 252. The second bevel gear 253 is coaxially provided with a driven gear 254 at an end of the second bevel gear 253. The driven gear 254 is engaged with a straight rack 255 at a side of the driven gear 254. The straight rack 255 is fixedly connected to a mounting frame 26 at an end of the straight rack 255.

When the telescopic rod 22 moves upwardly, the smoothing roller 24 is gradually lower than the suction head 10 to push the label into contact with the surface of the battery. Then, the telescopic rod 22 comes into contact with the driving gear 251 and pushes the driving gear 251 to rotate. Two first bevel gears 252 rotate accordingly and drive the corresponding second bevel gear 253 to rotate. The second bevel gear 253 rotates and drives the driven gear 254 to rotate to move the straight rack 255. Two straight racks 255 drive the two smoothing rollers 24 to move away from each other by means of the mounting frames 26. The smoothing roller 24 moves along the arc-shaped surface of the battery to flatten a raised portion of the label.

The disposed connection portion can use upward movement of the telescopic rod 22 to move the two smoothing rollers 24 away from each other. A smoothing roller 24 in contact with a surface of the label rolls along the arc-shaped surface of the battery, to smooth a position at two ends of the label that is raised due to the arc-shaped surface of the battery being not in contact with the surface of the battery, to prevent the label from folding or detaching due to other factors, ensuring normal grouping operation.

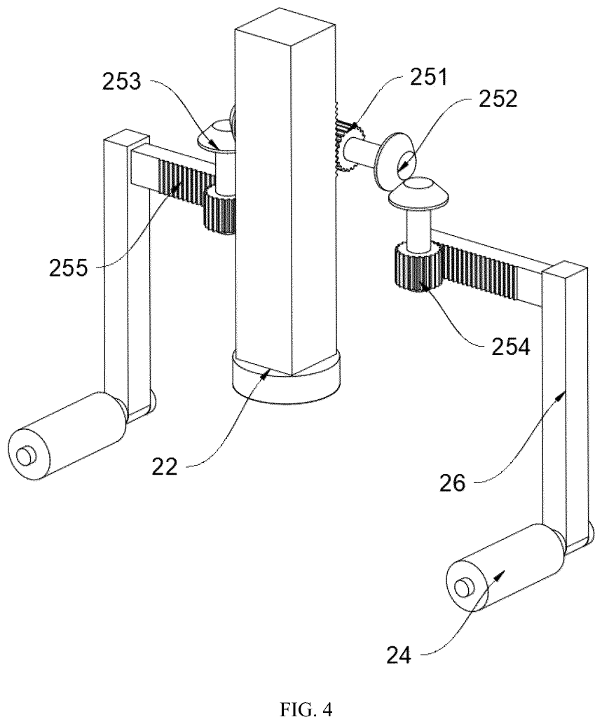

In FIG. 3 to FIG. 4, the connection portion is symmetrically arranged relative to a middle part of the telescopic rod 22. The telescopic rod 22 is not engaged with the driving gear 251 at a bottommost position of the telescopic rod 22.

After moving upwardly by a predetermined distance, the telescopic rod 22 is engaged with the driving gear 251. The smoothing roller 24 may come into contact with the surface of the battery. In addition, the smoothing roller 24 may move to a side when the telescopic rod 22 continues to retract. In this case, the smoothing roller 24 may move along the arc-shaped surface of the battery and push the label.

In FIG. 2 to FIG. 4, an end of the smoothing roller 24 is rotatably inserted into the mounting frame 26. The smoothing roller 24 is in rolling engagement with the surface of the battery.

The rotating smoothing roller 24 may change sliding friction with the arc-shaped surface of the battery into rolling friction, reducing an influence on the label, and avoiding a situation where information on a surface of the label is scratched, resulting in a failure of normal grouping.

The above embodiments are only intended to illustrate the technical solutions of the present disclosure, rather than to limit the present disclosure.

What is claimed is:

1. An automatic grouping method for a traction battery used in an electric vehicle, the method comprising:
step 1: collecting battery data:
conveying, by a main belt conveyor, a plurality of batteries to pass through a detection device in sequence, and making contact with, by the detection device, positive electrodes and negative electrodes of the plurality of batteries to obtain battery information;
step 2: storing and aggregating data:
transmitting, by the detection device, data of the battery information to a computer connected to the detection device, and storing, by the computer, the battery information in a predefined data table;
step 3: grouping the battery information:
grouping, by the computer, the plurality of batteries based on a grouping condition, labeling, by the computer, the plurality of batteries with a cut-off voltage, a discharge period, grouping information, and a date, and directly rejecting a battery that meets a screening condition;
step 4: printing and pasting a barcode:
printing, by the computer, labeled information on a label by means of a barcode printing device connected to the computer, and pasting, by a labeling device connected to the computer, the label on a corresponding battery; and
step 5: screening and grouping the plurality of batteries:
placing, by a manipulator connected to the computer based on the labeled information, the plurality of batteries on a secondary belt conveyor of a corresponding group, and processing and assembling the plurality of batteries in a same group into a complete traction battery.

2. The automatic grouping method for the traction battery used in the electric vehicle according to claim 1, wherein the grouping condition in the step 3 is:
setting a starting value of cut-off voltage data, and dividing the plurality of batteries into N large groups in sequence based on a predetermined cut-off voltage data interval;
setting a starting value of discharge period data in a same large group, and dividing the plurality of batteries in the same large group into N small groups in sequence based on a predetermined discharge period data interval; and
dividing, by the computer, the plurality of batteries into a corresponding small group in a corresponding large group based on the cut-off voltage and the discharge period, where N is a natural number greater than 1.

3. The automatic grouping method for the traction battery used in the electric vehicle according to claim 1, wherein the grouping condition in the step 3 is:
setting a starting value of cut-off voltage data, and dividing the plurality of batteries into N large groups in sequence based on a predetermined cut-off voltage data interval;
setting a starting value of discharge period data in a same large group, and dividing the plurality of batteries in the same large group into M small groups in sequence based on a predetermined discharge period data interval; and
dividing, by the computer, the plurality of batteries into a corresponding small group in a corresponding large group based on the cut-off voltage and the discharge period, where each of N and M is a natural number greater than 1, and N is different from M.

4. The automatic grouping method for the traction battery used in the electric vehicle according to claim 2, wherein the screening condition in the step 3 is: the cut-off voltage data of the battery is lower than the starting value of the cut-off voltage data, or the discharge period of the battery is lower than the starting value of the discharge period data.

5. The automatic grouping method for the traction battery used in the electric vehicle according to claim 3, wherein the screening condition in the step 3 is: the cut-off voltage data of the battery is lower than the starting value of the cut-off voltage data, or the discharge period of the battery is lower than the starting value of the discharge period data.

6. The automatic grouping method for the traction battery used in the electric vehicle according to claim 1, wherein the labeling device comprises a drive assembly, a connection assembly (20), and a suction head (10), wherein:
the connection assembly (20) is configured to connect the drive assembly and the suction head (10), and the connection assembly (20) comprises a mounting housing (21) and a telescopic rod (22), an end of the telescopic rod (22) being movably inserted into the mounting housing (21) in a vertical direction, a return spring (23) being fixedly connected between the telescopic rod (22) and the mounting housing (21); and
the drive assembly is configured to drive the suction head (10) by means of the connection assembly (20) to pick up the label from a label sheet, and the suction head (10) is configured to push the telescopic rod (22) upwardly to paste the label to a surface of the battery.

7. The automatic grouping method for the traction battery used in the electric vehicle according to claim 6, wherein the telescopic rod (22) has a first end located inside the mounting housing (21), and a second end located outside the mounting housing (21), the first end being connected to the return spring (23), and the second end being connected to the suction head (10).

8. The automatic grouping method for the traction battery used in the electric vehicle according to claim 6, wherein the connection assembly (20) further comprises a smoothing component, the smoothing component comprising a connection portion and a smoothing roller (24), and the connection portion being configured to move two smoothing rollers (24) towards or away from each other by using a reciprocating movement of the telescopic rod (22) in the vertical direction.

9. The automatic grouping method for the traction battery used in the electric vehicle according to claim 8, wherein the two smoothing rollers (24) are located at two sides of the telescopic rod (22), respectively.

10. The automatic grouping method for the traction battery used in the electric vehicle according to claim 8, wherein the connection portion comprises a driving gear (251), and the telescopic rod (22) has a toothed surface formed at a surface of the telescopic rod (22), the driving gear (251) being engaged into the toothed surface, wherein:
first bevel gears (252) are coaxially arranged at two ends of the driving gear (251), each of the first bevel gears (252) is engaged with a second bevel gear (253) at a side of the first bevel gear (252), the second bevel gear (253) is coaxially provided with a driven gear (254) at an end of the second bevel gear (253), the driven gear (254) is engaged with a straight rack (255) at a side of the driven gear (254), and the straight rack (255) is fixedly connected to a mounting frame (26) at an end of the straight rack (255).

11. The automatic grouping method for the traction battery used in the electric vehicle according to claim 10, wherein the connection portion is symmetrically arranged relative to a middle part of the telescopic rod (22), and the telescopic rod (22) is not engaged with the driving gear (251) at a bottommost position of the telescopic rod (22).

12. The automatic grouping method for the traction battery used in the electric vehicle according to claim 10, wherein an end of the smoothing roller (24) is rotatably inserted into the mounting frame (26), and the smoothing roller (24) is in rolling engagement with the surface of the battery.

13. The automatic grouping method for the traction battery used in the electric vehicle according to claim 12, wherein after the telescopic rod (22) moves upwardly by a predetermined distance, the toothed surface of the telescopic rod (22) is engaged with the driving gear (251), the telescopic rod (22) pushes the driving gear (251) to rotate, the driving gear (251) drives two first bevel gears (252) to rotate, the two first bevel gears (252) drive the second bevel gears (253) corresponding to the two first bevel gears (252) to rotate respectively, the second bevel gears (253) drive the driven gear (254) to rotate and enable the straight rack (255) to move, and two straight racks (255) drive the two smoothing rollers (24) to move away from each other by means of the mounting frames (26).
